(19) United States
(12) Patent Application Publication
(10) Pub. No.: US 2022/0306900 A1
(43) Pub. Date: Sep. 29, 2022

(54) POLISHING COMPOSITION, POLISHING METHOD AND METHOD FOR PRODUCING SEMICONDUCTOR SUBSTRATE

(71) Applicant: FUJIMI INCORPORATED, Aichi (JP)

(72) Inventor: Ryota Mae, Aichi (JP)

(21) Appl. No.: 17/700,840

(22) Filed: Mar. 22, 2022

(30) Foreign Application Priority Data
Mar. 24, 2021 (JP) 2021-049532

(51) Int. Cl. C09G 1/02

(52) U.S. Cl. CPC C09G 1/02; H01L 21/304

(57) ABSTRACT

Provided is a polishing composition capable of polishing an object to be polished containing polycrystalline silicon doped with an n-type impurity at a high polishing speed.

The polishing composition contains abrasive grains and a dispersing medium, wherein: the abrasive grains contain first silica particles having a silanol group density of higher than 0 group/nm² and 4 groups/nm² or less and second silica particles having a silanol group density of higher than 4 groups/nm² and 12 groups/nm² or less; and the pH is higher than 6.

### CROSS-REFERENCE TO RELATED APPLICATION

The present application is based on Japanese Patent Application No. 2021-049532 filed on Mar. 24, 2021 and the disclosed content thereof is incorporated herein by reference in their entirety.

### BACKGROUND

### 1. Technical Field

The present invention relates to a polishing composition, a polishing method and a method for producing a semiconductor substrate.

### 2. Description of Related Arts

In recent years, associated with multilayer wiring of semiconductor substrate surfaces, a technique for flattening a semiconductor substrate by polishing, namely a chemical mechanical polishing (CMP) technique, is used in producing a device. CMP is a method for flattening a surface of an object to be polished (polishing object) such as a semiconductor substrate using a polishing composition (slurry) containing abrasive grains such as silica, alumina, or ceria, an anti-corrosion agent, a surfactant, or the like. The object to be polished (polishing object) is silicon, polysilicon, silicon oxide film (silicon oxide), silicon nitride, a wiring or a plug made of metal, or the like.

For example, as a technique for polishing a polysilicon film provided on a silicon substrate including an isolation region, JP 2007-103515 A discloses a polishing method including a step of preliminarily polishing using a preliminary polishing composition containing abrasive grains, alkali, a water-soluble polymer and water, and a step of finish polishing using a finish polishing composition containing abrasive grains, alkali, a water-soluble polymer and water.

### SUMMARY

Recently, a substrate containing polycrystalline silicon (polysilicon) doped with an impurity has come to be used as a semiconductor substrate, resulting in a new requirement of polishing the substrate. Such requirement has almost never been examined.

Therefore, an object of the present invention is to provide a means capable of polishing an object to be polished containing polycrystalline silicon doped with an n-type impurity at a high polishing speed.

The inventors of the present invention have intensively studied to solve the above problems. As a result, the inventors have discovered that the above problems can be solved by a polishing composition containing abrasive grains and a dispersing medium, wherein: the abrasive grains contain first silica particles having a silanol group density of higher than 0 group/nm² and 4 groups/nm² or less and second silica particles having a silanol group density of higher than 4 groups/nm² and 12 groups/nm² or less; and the pH is higher than 6, and thus have completed the present invention.

### DETAILED DESCRIPTION

Embodiments of the present invention will be described below, but the present invention is not limited to only the following embodiments. In addition, unless otherwise specified, operation and measurement of physical properties and the like are performed under conditions of room temperature (20° C. to 25° C.)/relative humidity (40% RH to 50% RH). Further, as used herein, the term “X to Y” representing a numerical range refers to “X or more and Y or less”.

### <Polishing Composition>

The present invention is a polishing composition that is used for polishing an object to be polished and contains abrasive grains and a dispersing medium, wherein the abrasive grains contain first silica particles having a silanol group density of higher than 0 group/nm² and 4 groups/nm² or less and second silica particles having a silanol group density of higher than 4 groups/nm² and 12 groups/nm² or less and the pH is higher than 6. The polishing composition of the present invention having such configuration is capable of polishing an object to be polished containing polycrystalline silicon doped with an n-type impurity at a high polishing speed.

According to the present invention, provided is a polishing composition which is capable of polishing an object to be polished containing polycrystalline silicon doped with an n-type impurity at a high polishing speed.

The reason why the polishing composition of the present invention exhibits the above effect is not necessarily clear, but can be considered as follows.

A polishing composition is generally used for polishing an object to be polished by physical action, which is a frictional action of rubbing the surface of a substrate with the composition, and chemical action of components other than abrasive grains on the surface of a substrate, as well as a combination thereof. Therefore, the form or the type of abrasive grains will have a major impact on the polishing speed.

The polishing composition of the present invention contains, as abrasive grains, first silica particles having a silanol group density of higher than 0 group/nm² and 4 groups/nm² or less (hereinafter, may also be referred to as “(first) silica particles having a low silanol group density”) and second silica particles having a silanol group density of higher than 4 groups/nm² and 12 groups/nm² or less (hereinafter, may also be referred to as “(second) silica particles having a high silanol group density”). Specifically, the polishing composition of the present invention contains two types of silica particles differing in silanol group density. Polycrystalline silicon is (and similarly polycrystalline silicon doped with an n-type impurity is) highly hydrophobic. In general, abrasive grains having a lower silanol group density are more hydrophobic and contain a lower amount of bound water, and thus can more easily approach a hydrophobic object to be polished. Further, abrasive grains having a higher silanol group density are more hydrophilic and contain a higher amount of bound water, and thus approach a hydrophobic film with difficulty. Therefore, when polishing, first silica particles having a low silanol group density contained in the polishing composition approach an object to be polished so as to be able to sufficiently apply mechanical force to the object to be polished (surface to be polished) and to suitably polish the object. When polishing, second silica particles having a high silanol group density contained in the polishing composition are located distant from a surface to be polished, and play a role in pressing the first silica particles against an object to be polished. Hence, the second silica particles further intensify the mechanical force to be applied by the first silica particles to an object to be polished, enabling the first silica particles to polish the object to be polished with a stronger mechanical force. Therefore, the present invention is a result of discovering a combination of abrasive grains, which is capable of effectively acting on a surface to be polished.

The polishing composition of the present invention has a pH of higher than 6. The polishing composition of the present invention, wherein an object to be polished is an object to be polished containing polycrystalline silicon doped with an n-type impurity, has a pH of higher than 6, so that polycrystalline silicon doped with an n-type impurity can be efficiently polished. Hence, it is considered that the above configuration of abrasive grains exhibits even more significant effects.

As described above, it is considered that the first silica particles have a relatively low silanol group density and the second silica particles have a relatively high silanol group density, so that two types of abrasive grains differing in adsorptiveness to an object to be polished can act differently on the object to be polished, thereby improving the polishing speed.

Moreover, the inventors of the present invention have discovered that when first silica particles approaching an object to be polished and second silica particles located even more distant from the object to be polished than the first silica particles are present (specifically, when silica particles having a low silanol group density and silica particles having a high silanol group density are present), the two types of silica particles having different particle sizes result in further improvement of the effect of the present invention (high polishing speed). The second silica particles apply a force (the force of pressing the first silica particles against an object to be polished) to the first silica particles, so that the first silica particles can apply strong mechanical force to an object to be polished. In this case, the larger the particle size, the stronger the force to be applied. Further, the smaller the particle size of the first silica particles for polishing an object to be polished, the smaller the area of contact with a surface to be polished and the higher the energy density to be applied to the surface to be polished. Accordingly, the inventors of the present invention have discovered that since the first silica particles approaching an object to be polished have a relatively small average secondary particle size, and the second silica particles located distant from the object to be polished have a relatively large average secondary particle size, the polishing speed is further improved.

As described above, it is considered, in the polishing composition of the present invention, the first silica particles and the second silica particles located differently with respect to an object to be polished when polishing have particle sizes different from each other, and thus the polishing composition has further improved polishing property. However, such mechanism is speculative, and it goes without saying that the mechanism does not limit the technical scope of the present invention.

[Object to be Polished]

The object to be polished according to the present invention contains a polycrystalline silicon (polysilicon) film doped with an n-type impurity. Specifically, the object to be polished according to the present invention is used in application for polishing objects to be polished containing a polycrystalline silicon film doped with an n-type impurity.

Examples of an n-type impurity, with which polycrystalline silicon is doped, include group 15 elements such as phosphorus (P), arsenic (As), bismuth (Bi), and antimony (Sb). Of these n-type impurities, phosphorus is preferred.

The lower limit of the content (doping level) of an n-type impurity, with which polycrystalline silicon is doped, is not particularly limited, but is preferably 1 at % or more, more preferably 2.5 at % or more, and further preferably 5 at % or more with respect to the total atomic percentage, 100 at %, of polycrystalline silicon and the impurity. Further, the upper limit of the content (doping level) of an n-type impurity, with which polycrystalline silicon is doped, is not particularly limited, but is preferably 50 at % or less, more preferably 30 at % or less, and further preferably 25 at % or less with respect to the total atomic percentage, 100 at %, of polycrystalline silicon and the impurity. Note that the content of an n-type impurity, with which polycrystalline silicon is doped, is calculated by a method described in later-described Examples using a multifunctional scanning X-ray photoelectron spectrometer (XPS).

The object to be polished according to the present invention may contain, in addition to a polycrystalline silicon (polysilicon) film doped with an n-type impurity, other materials. Examples of other materials include silicon nitride (SiN), silicon carbonitride (SiCN), silicon oxide, undoped polycrystalline silicon (undoped polysilicon), undoped non-crystalline silicon (undoped amorphous silicon), metal and SiGe.

Examples of a film containing silicon oxide include a TEOS (Tetraethyl Orthosilicate)-type silicon oxide film (hereinafter, also simply referred to as “TEOS film”) generated using tetraethyl orthosilicate as a precursor, an HDP (High Density Plasma) film, an USG (Undoped Silicate Glass) film, a PSG (Phosphorus Silicate Glass) film, a BPSG (Boron-Phospho Silicate Glass) film, and an RTO (Rapid Thermal Oxidation) film.

Examples of the above metal include tungsten, copper, aluminium, cobalt, hafnium, nickel, gold, silver, platinum, palladium, rhodium, ruthenium, iridium, and osmium.

The object to be polished according to the present invention preferably further contains a silicon oxide film or a silicon nitride film and more preferably further contains a silicon oxide film. Hence, it is preferable to use the polishing composition of the present invention for polishing an object to be polished containing a polycrystalline silicon (polysilicon) film doped with an n-type impurity, and a silicon oxide film or a silicon nitride film. It is more preferable to use the polishing composition of the present invention for polishing an object to be polished containing a polycrystalline silicon (polysilicon) film doped with an n-type impurity and a silicon oxide film.

In an embodiment, the object to be polished of the present invention further contains, in addition to a polycrystalline silicon film doped with an n-type impurity, at least one of a silicon oxide film (preferably a TEOS film) and a silicon nitride film. The polishing composition of the present invention is capable of selectively polishing a polycrystalline silicon film doped with an n-type impurity, when a silicon oxide film (preferably a TEOS film) and/or silicon nitride film is polished together with the polycrystalline silicon film doped with the n-type impurity. Specifically, even when an object to be polished containing a polycrystalline silicon film doped with an n-type impurity together with a silicon oxide film (preferably a TEOS film) and/or a silicon nitride film is polished, the polycrystalline silicon film doped with the n-type impurity can be selectively polished at a high polishing speed. Accordingly, an effect of being able to maintain or suppress the polishing speed for polishing a silicon oxide film (preferably a TEOS film) and/or a silicon nitride film while improving the polishing speed for polishing a polycrystalline silicon film doped with an n-type impurity, specifically, an effect of improving the ratio (selection ratio) of the polishing speed for polishing the polycrystalline silicon film doped with the n-type impurity to the polishing speed for polishing the silicon oxide film and/or the silicon nitride film can be also obtained.

In an embodiment, the object to be polished of the present invention can improve the polishing speed for polishing a silicon oxide film (preferably a TEOS film) and/or a silicon nitride film while improving the polishing speed for polishing a polycrystalline silicon film doped with an n-type impurity, and can improve the ratio (selection ratio) of the polishing speed for the polycrystalline silicon film doped with the n-type impurity to the polishing speed for the silicon oxide film and/or the silicon nitride film. Such polishing composition resulting in high polishing speeds for a silicon oxide film (preferably a TEOS film) and/or a silicon nitride film is preferred, since the polishing composition can maintain a high polishing speed without lowering the polishing speed even when a natural oxide film is formed.

[Abrasive Grains]

The polishing composition of the present invention contains abrasive grains. In the polishing composition of the present invention, the abrasive grains contain first silica particles having a silanol group density of higher than 0 group/nm² and 4 groups/nm² or less and second silica particles having a silanol group density of higher than 4 groups/nm² and 12 groups/nm² or less. In an embodiment, the abrasive grains are composed of first silica particles and second silica particles. The term “silanol group density” used herein refers to the number of silanol groups per unit area of the surface of silica particles. The silanol group density is an indicator representing the electric characteristics or chemical characteristics of the surface of silica particles.

The silanol group density used herein is found via calculation based on the specific surface area measured by a BET method and the amount of silanol groups measured by titration. For example, the average silanol group density (unit: group/nm²) of the surface of silica (polishing abrasive grains) can be calculated by a Sears titration method using neutralization titration described in G. W. Sears's “Analytical Chemistry, vol. 28, No. 12, 1956, 1982 to 1983”. The “Sears titration method” is an analytical technique that is generally employed by colloidal silica manufacturers to evaluate silanol group density, which involves calculating based on the amount of a sodium hydroxide aqueous solution required for changing the pH from 4 to 9. Measurement of silanol group density will be described in detail in the following examples.

In an embodiment of the present invention, selection or the like of a method for producing abrasive grains is effective to set the number of silanol groups per unit surface area of abrasive grains to be higher than 0 group/nm² and 4 groups/nm² or less or higher than 4 groups/nm² and 12 groups/nm² or less. For example, heat treatment such as sintering is suitably performed. In an embodiment of the present invention, sintering is performed by, for example, maintaining abrasive grains (e.g., silica) under an environment at 120° C. to 200° C. for 30 minutes or longer. Through such heat treatment, the number of silanol groups on the surface of abrasive grains can be controlled to be a desired numerical value, such as a value of higher than 0 group/nm² and 4 groups/nm² or less, or higher than 4 groups/nm² and 12 groups/nm² or less. Through such special treatment, the number of silanol groups on the surface of abrasive grains can be set to be higher than 0 group/nm² and 4 groups/nm² or less, or higher than 4 groups/nm² and 12 groups/nm² or less.

The first silica particles have a silanol group density of preferably 0.5 group/nm² or more and 4 groups/nm² or less, more preferably 0.6 group/nm² or more and 3.8 groups/nm² or less, further preferably 0.8 group/nm² or more and 3.6 groups/nm² or less, particularly preferably 0.9 group/nm² or more and 3.5 groups/nm² or less, and most preferably 1 group/nm² or more and 3 groups/nm² or less. The first silica particles have a silanol group density within the above ranges, so that the first silica particles can approach an object to be polished when polishing, and the first silica particles effectively apply mechanical force to the object to be polished.

The second silica particles have a silanol group density of preferably 4.5 groups/nm² or more and 12 groups/nm² or less, more preferably higher than 5 groups/nm² and 12 groups/nm² or less, further preferably 5.5 groups/nm² or more and 12 groups/nm² or less, particularly preferably higher than 6 groups/nm² and 12 groups/nm² or less, and most preferably higher than 6 groups/nm² and 11.5 groups/nm² or less. The second silica particles have a silanol group density within the above ranges, so that the second silica particles are located more distant from an object to be polished than the first silica particles when polishing, and the second silica particles effectively apply the force (the force of pressing the first silica particles against an object to be polished) to the first silica particles.

The first silica particles and the second silica particles are more preferably colloidal silica. Examples of a method for producing colloidal silica include a soda silicate method and a sol-gel method, and colloidal silica produced by any of these methods is suitably used as the first silica particles and the second silica particles of the present invention. However, from the viewpoint of reducing metal impurities, colloidal silica produced by a sol-gel method that enables high-purity production is preferred.

Furthermore, the first silica particles and the second silica particles may be surface-modified, as long as the silanol group density satisfies the above ranges. For example, the first silica particles and the second silica particles may also be colloidal silica with organic acid immobilized thereto. Such immobilization of an organic acid to the surface of the colloidal silica contained in the polishing composition is performed by, for example, chemical bonding of functional groups of the organic acid with the surface of the colloidal silica. Simple coexistence of colloidal silica and the organic acid cannot achieve the immobilization of the organic acid to the colloidal silica. If sulfonic acid that is a type of such organic acid is immobilized to the colloidal silica, for example, this can be achieved by a method described in “Sulfonic acid-functionalized silica through quantitative oxidation of thiol groups”, Chem. Commun. 246-247 (2003). Specifically, after coupling of a silane coupling agent having thiol groups such as 3-mercaptopropyltrimethoxysilane with the colloidal silica, the thiol groups are oxidized with hydrogen peroxide, and thus the colloidal silica with the sulfonic acid immobilized to the surface thereof can be obtained. Alternatively, if carboxylic acid is immobilized to colloidal silica, for example, this can be performed by a method described in “Novel Silane Coupling Agents Containing a Photolabile 2-Nitrobenzyl Ester for Introduction of a Carboxy Group on the Surface of Silica Gel”, Chemistry Letters, 3, 228-229 (2000). Specifically, after coupling of a silane coupling agent containing photolabile 2-nitrobenzyl ester with the colloidal silica, the colloidal silica is irradiated with light, and thus the colloidal silica with carboxylic acid immobilized to the surface thereof can be obtained.

In the polishing composition of the present invention, examples of abrasive grains may include abrasive grains other than the first silica particles and the second silica particles (hereinafter, other abrasive grains). Types of other abrasive grains contained in the polishing composition of the present invention are not particularly limited, and examples thereof include oxides such as silica other than the first silica particles and the second silica particles, alumina, zirconia, and titania. Other abrasive grains can be used singly or in combinations of two or more thereof. As other abrasive grains, a commercial product thereof or a synthetic product thereof may also be used.

Note that in descriptions given below, when a term is referred to as “abrasive grains”, specifically, unless otherwise specified as first silica particles or second silica particles, such term refers to first silica particles, second silica particles and other abrasive grains without particular distinction.

The lower limit of the average primary particle size of the first silica particles is preferably 5 nm or more, more preferably 7 nm or more, further preferably 10 nm or more, particularly preferably 15 nm or more, and most preferably 20 nm or more. The upper limit of the average primary particle size of the first silica particles is preferably 300 nm or less, more preferably 250 nm or less, further preferably 200 nm or less, particularly preferably 180 nm or less, and most preferably 150 nm or less. With the lower and the upper limits within such ranges, the polishing speed for an object to be polished can be even more improved.

The lower limit of the average primary particle size of the second silica particles is preferably 10 nm or more, more preferably 15 nm or more, further preferably 20 nm or more, particularly preferably 25 nm or more, and most preferably 30 nm or more. The upper limit of the average primary particle size of the second silica particles is preferably 400 nm or less, more preferably 300 nm or less, further preferably 250 nm or less, particularly preferably 200 nm or less, and most preferably 180 nm or less. With the lower and the upper limits within such ranges, the polishing speed for an object to be polished can be even more improved.

The value of the average primary particle size of abrasive grains can be calculated based on the specific surface area measured using the BET method.

The lower limit of the average secondary particle size of the first silica particles is preferably 10 nm or more, more preferably 20 nm or more, further preferably 30 nm or more, particularly preferably 40 nm or more, and most preferably 50 nm or more. Further, the upper limit of the average secondary particle size of the first silica particles is preferably 200 nm or less, more preferably 180 nm or less, further preferably 150 nm or less, particularly preferably 100 nm or less, and most preferably 80 nm or less. Specifically, the average secondary particle size of the first silica particles is preferably 10 nm or more and 200 nm or less, more preferably 20 nm or more and 180 nm or less, further preferably 30 nm or more and 150 nm or less, particularly preferably 40 nm or more and 100 nm or less, and most preferably 10 nm or more and 80 nm or less. With the lower and the upper limits within such ranges, the polishing speed for an object to be polished can be even more improved.

The lower limit of the average secondary particle size of the second silica particles is preferably 20 nm or more, more preferably 40 nm or more, further preferably 50 nm or more, particularly preferably 80 nm or more, and most preferably 100 nm or more. Further, the upper limit of the average secondary particle size of the second silica particles is preferably 300 nm or less, more preferably 280 nm or less, further preferably 250 nm or less, particularly preferably 200 nm or less, and most preferably 180 nm or less. Specifically, the average secondary particle size of the second silica particles is preferably 20 nm or more and 300 nm or less, more preferably 40 nm or more and 280 nm or less, further preferably 50 nm or more and 250 nm or less, particularly preferably 80 nm or more and 200 nm or less, and most preferably 100 nm or more and 180 nm or less. With the lower and the upper limits within such ranges, the polishing speed for an object to be polished can be even more improved.

In an embodiment of the present invention, the average secondary particle size of the first silica particles is smaller than the average secondary particle size of the second silica particles. This further improves the polishing speed when polishing is performed with the polishing composition.

Further, in an embodiment of the present invention, the average secondary particle size of the first silica particles is smaller than the average secondary particle size of the second silica particles, the average secondary particle size of the first silica particles is 10 nm or more and 200 nm or less, and the average secondary particle size of the second silica particles is 20 nm or more and 300 nm or less. This further improves the polishing speed when polishing is performed with the polishing composition.

Note that the average secondary particle size of abrasive grains can be measured by, for example, a dynamic light scattering method represented by a laser diffraction/scattering method. Specifically, the average secondary particle size of abrasive grains corresponds to the particle diameter D50 when the accumulated mass of particles from the particulate side reaches 50% of the total mass of particles in the particle size distribution of abrasive grains found by the laser diffraction/scattering method.

The average degree of association of abrasive grains is preferably 4.0 or less, more preferably 3.0 or less, and further preferably 2.5 or less. As the average degree of association of abrasive grains decreases, the chances of forming defects on the surface of an object to be polished can be even more reduced. Further, the average degree of association of abrasive grains is preferably 1.5 or more, and more preferably 1.8 or more. There is an advantage that as the average degree of association of abrasive grains increases, the speed of polishing with the use of the polishing composition is improved. Note that the average degree of association of abrasive grains can be obtained by dividing the value of the average secondary particle size of abrasive grains by the value of the average primary particle size.

The sizes of abrasive grains (average particle size etc.) can be appropriately controlled by selection or the like of a method for producing abrasive grains.

The lower limit of the content (concentration) of abrasive grains in the polishing composition according to an embodiment of the present invention is preferably 0.2 mass % or more, more preferably 0.3 mass % or more, and further preferably 0.5 mass % or more with respect to the polishing composition. Moreover, in the polishing composition of the present invention, the upper limit of the content of abrasive grains is preferably 20 mass % or less, more preferably 15 mass % or less, further preferably 10 mass % or less, and even more preferably 5 mass % or less with respect to the polishing composition. With the limits within such ranges, the polishing speed can be even more improved. Note that when the polishing composition contains 2 or more types of abrasive grains, the content of the abrasive grains means the total amount thereof.

In an embodiment of the present invention, the mass ratio of the first silica particles to the second silica particles is preferably first silica particles:second silica particles=1:10 to 10:1, more preferably first silica particles:second silica particles=1:5 to 5:1, and further preferably first silica particles:second silica particles=1:2 to 2:1. With the mass ratio within such ranges, the polishing speed can be more improved.

[Polishing Speed-Improving Agent]

The polishing composition of the present invention further contains, in an embodiment, at least one polishing speed-improving agent selected from the group consisting of aminoethylpiperazine and ammonia. Here, the term “polishing speed-improving agent” refers to a compound having a function of improving the polishing speed when polishing using the polishing composition through addition of the agent to the composition. The polishing speed-improving agent serves to chemically polish a surface of an object to be polished and to improve the dispersion stability of the polishing composition. Moreover, the polishing speed-improving agent contained in the polishing composition of the present invention has an effect of increasing the electrical conductivity of the polishing composition. Therefore, it is considered that the polishing speed when polishing is performed with the polishing composition is further improved.

In the embodiments of the present invention, the lower limit of the content of the polishing speed-improving agent in the polishing composition is, with respect to the polishing composition, preferably 0.001 mass % or more, more preferably 0.005 mass % or more, further preferably 0.01 mass % or more, particularly preferably 0.05 mass % or more, and most preferably 0.07 mass % or more. With such lower limits, the polishing speed is even more improved. The upper limit of the content of the polishing speed-improving agent in the polishing composition is, with respect to the polishing composition, preferably 10 mass % or less, more preferably 8 mass % or less, further preferably 5 mass % or less, particularly preferably 3 mass % or less, and most preferably 1 mass % or less. With such upper limits, stable slurries can be obtained without aggregation.

[pH and pH Adjusting Agent]

The polishing composition of the present invention has a pH of higher than 6. If the pH is 6 or less, the polishing speed for polishing an object to be polished cannot be improved. The pH of the polishing composition of the present invention may be higher than 6, but is preferably 7 or more, more preferably 7.5 or more, further preferably 8 or more, even more preferably 9 or more, particularly preferably 9.5 or more, and most preferably 10 or more. If the pH is higher than 6, even when an object to be polished containing a polycrystalline silicon doped with an n-type impurity and silicon oxide film (preferably, a TEOS film) and/or a silicon nitride film is polished, the polycrystalline silicon doped with the n-type impurity can be selectively polished at a high polishing speed. The upper limit of the pH is, practically, preferably 13 or less, and more preferably 12.5 or less.

The polishing composition of the present invention may further contain a pH adjusting agent as necessary. The pH adjusting agent is used for adjusting the pH of the polishing composition to a desired value.

Examples of the pH adjusting agent contained in the polishing composition of the present invention include inorganic acid, organic acid, and alkali. These may be used singly or in combinations of two or more thereof.

Specific examples of an inorganic acid that can be used as a pH adjusting agent include hydrochloric acid, sulfuric acid, nitric acid, hydrofluoric acid, boric acid, carbonic acid, hypophosphorous acid, phosphorous acid and phosphoric acid. Particularly preferred examples thereof are hydrochloric acid, sulfuric acid, nitric acid, or phosphoric acid.

Specific examples of an organic acid that can be used as a pH adjusting agent include formic acid, acetic acid, propionic acid, butyric acid, valeric acid, 2-methyl butyric acid, n-hexanoic acid, 3,3-dimethylbutyric acid, 2-ethylbutyric acid, 4-methylvaleric acid, n-heptanoic acid, 2-methylhexanoic acid, n-octanoic acid, 2-ethyl hexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, citric acid, lactic acid, diglycolic acid, 2-furancarboxylic acid, 2,5-furandicarboxylic acid, 3-furancarboxylic acid, 2-tetrahydrofuroic acid, methoxyacetic acid, methoxyphenylacetic acid and phenoxyacetic acid. Organic sulfuric acid such as methansulfonic acid, ethanesulfonic acid and isethionic acid may also be used. Particularly preferred examples thereof are dicarboxylic acid such as malonic acid, succinic acid, glutaric acid, adipic acid, pimelic acid, maleic acid, phthalic acid, malic acid and tartaric acid, as well as tricarboxylic acid such as citric acid.

Instead of an inorganic acid or an organic acid, or with a combination with an inorganic acid or an organic acid, a salt such as an alkali metal salt of an inorganic acid or an organic acid may also be used as a pH adjusting agent. In the case of a combination of a weak acid and a strong base, that of a strong acid and a weak base, or that of a weak acid and a weak base, the pH buffering action can be expected.

Specific examples of alkali that can be used as a pH adjusting agent can include ammonia, sodium hydroxide, potassium hydroxide, and tetramethylammonium hydroxide. The content of a pH adjusting agent can be selected through adequate adjustment to such an extent that the effects of the present invention are exhibited.

In an embodiment of the present invention, the polishing composition further contains a pH adjusting agent, and the pH adjusting agent contains potassium hydroxide. The pH adjusting agent contains potassium hydroxide, so that the electrical conductivity can be easily adjusted within a preferred range, resulting in an advantageous effect of further improving the polishing speed.

Note that the pH of the polishing composition can be measured with a pH meter, for example. Specifically, after 3-point calibration using a pH meter (e.g., manufactured by HORIBA, Ltd., model: LAQUA) or the like, and a standard buffer solution (phthalate pH buffer solution pH: 4.01 (25° C.), neutral phosphate pH buffer solution pH: 6.86 (25° C.), carbonate pH buffer solution pH: 10.01 (25° C.)), a glass electrode is placed in the polishing composition, and then after two or more minutes, the stabilized value is measured, and thus the pH of the polishing composition can be measured.

[Dispersing Medium]

The polishing composition of the present invention contains a dispersing medium for dispersing each component. Examples of the dispersing medium can include water, alcohols such as methanol, ethanol, and ethylene glycol, ketones such as acetone, and mixtures thereof. Of these, water is preferred as a dispersing medium. Specifically, according to a preferred embodiment of the present invention, examples of a dispersing medium include water. According to a more preferred embodiment of the present invention, the dispersing medium is substantially composed of water. Note that the above “substantially” is intended to mean that a dispersing medium other than water can be contained as long as the purpose and the effects of the present invention can be achieved. More specifically, the dispersing medium includes preferably 90 mass % or more and 100 mass % or less of water and 0 mass % or more and 10 mass % or less of a dispersing medium other than water, and more preferably 99 mass % or more and 100 mass % or less of water and 0 mass % or more and 1 mass % or less of a dispersing medium other than water. Most preferably, the dispersing medium is water.

Water containing impurities in an amount as low as possible is preferred as the dispersing medium from the viewpoint of not inhibiting the action of components contained in the polishing composition. Specifically, pure water or ultra-pure water, which is obtained by removing foreign matters through a filter after removal of impurity ions using an ion exchange resin, or distilled water is more preferred.

[Other Components]

The polishing composition of the present invention may further contain as necessary a known additive that can be used for the polishing composition, such as a complexing agent, an antiseptic agent, and an antifungal agent, as long as the effects of the present invention are not significantly inhibited. However, according to an embodiment of the present invention, the polishing composition substantially contains no oxidizing agent.

In the polishing composition of the present invention, the total content of abrasive grains, a dispersing medium, at least one polishing speed-improving agent selected from the group consisting of aminoethylpiperazine and ammonia, and a pH adjusting agent is preferably higher than 99 mass % (upper limit: 100 mass %) with respect to the total mass (100 mass %) of the polishing composition. The polishing composition of the present invention may also be composed of abrasive grains, a dispersing medium, at least one polishing speed-improving agent selected from the group consisting of aminoethylpiperazine and ammonia, a pH adjusting agent, and an antifungal agent (the above total content=100 mass %). More preferably, the polishing composition is composed of abrasive grains, a dispersing medium, at least one polishing speed-improving agent selected from the group consisting of aminoethylpiperazine and ammonia, and a pH adjusting agent (the above total content=100 mass %). According to these embodiments, even when an object to be polished containing polycrystalline silicon doped with an n-type impurity, a silicon oxide film (preferably a TEOS film) and/or a silicon nitride film is polished, the polycrystalline silicon doped with the n-type impurity can be selectively polished at a high polishing speed. Note that the expression “contains substantially no . . . ” refers to, in addition to a concept such that the polishing composition contains none, a case in which the polishing composition contains a component(s) in an amount of 0.1 mass % or less.

[Electrical Conductivity of Polishing Composition]

The lower limit of the electrical conductivity of the polishing composition of the present invention is preferably 0.1 mS/cm or more, more preferably 0.3 mS/cm or more, further preferably 0.5 mS/cm or more, particularly preferably 0.8 mS/cm or more, and most preferably 0.9 mS/cm or more. Further, the upper limit of the electrical conductivity of the polishing composition of the present invention is preferably 6 mS/cm or less, more preferably 5 mS/cm or less, further preferably 4.5 mS/cm or less, particularly preferably 4 mS/cm or less, and most preferably 3.5 mS/cm or less. The electrical conductivity of the polishing composition within the above ranges leads to an advantageous effect of further improving the polishing speed. Note that the electrical conductivity of the polishing composition is a value measured using a desktop-type electrical conductivity meter (manufactured by HORIBA, Ltd., Model No.: DS-71).

[Method for Producing Polishing Composition]

A method for producing the polishing composition of the present invention is not particularly limited. For example, the polishing composition can be obtained by mixing and stirring abrasive grains, and other components as necessary in a dispersing medium (e.g., water). Each component is as described in detail above.

Temperature at which each component is mixed is not particularly limited, and the temperature is preferably 10° C. or higher and 40° C. or lower, and the mixture may also be heated in order to increase the rate of dissolution. Further the time for mixing is not particularly limited, as long as the mixture can be mixed uniformly.

[Polishing Method and Method for Producing Semiconductor Substrate]

As described above, the polishing composition of the present invention is suitably used for polishing an object to be polished containing a polycrystalline silicon film doped with an n-type impurity. Therefore, the present invention provides a method for polishing an object to be polished containing a polycrystalline silicon film doped with an n-type impurity using the polishing composition of the present invention. Specifically, the present invention encompasses a polishing method including a step of polishing an object to be polished containing a polycrystalline silicon film doped with an n-type impurity using the polishing composition of the present invention. Further, the present invention provides a method for producing a semiconductor substrate including a step of polishing a semiconductor substrate containing a polycrystalline silicon film doped with an n-type impurity by the above polishing method.

As a polishing apparatus, it is possible to use a general polishing apparatus provided with a holder for holding a substrate or the like having an object to be polished, a motor or the like having a changeable rotation number, and a platen to which a polishing pad (polishing cloth) can be attached.

As the polishing pad, a general nonwoven fabric, polyurethane, a porous fluororesin, or the like can be used without any particular limitation. The polishing pad is preferably grooved such that a polishing liquid can be stored therein.

Regarding polishing conditions, for example, the rotational speed of a platen is preferably 10 rpm (0.17 s⁻¹) or more and 500 rpm (8.3 s⁻¹) or less. The pressure (polishing pressure) applied to a substrate having an object to be polished is preferably 0.5 psi (3.4 kPa) or more and 10 psi (68.9 kPa) or less. A method for supplying the polishing composition to a polishing pad is also not particularly limited. For example, a method for continuously supplying a polishing composition using a pump or the like is employed. The amount to be supplied is not limited, but a surface of the polishing pad is preferably covered all the time with the polishing composition of the present invention.

After completion of polishing, the substrate is cleaned in running water, water droplets adhered onto the substrate are removed using a spin dryer or the like for drying, and thus the substrate having a polycrystalline silicon film doped with an n-type impurity is obtained.

The polishing composition of the present invention may be of a one-component type or a multi-component type including a two-component type. Further, the polishing composition of the present invention may be prepared by, for example, diluting 10 or more times a stock solution of the polishing composition using a diluent such as water.

[Polishing Speed]

In the present invention, the speed (polishing speed) of polishing a polycrystalline silicon film doped with an n-type impurity is preferably 1000 Å/min or more and 7000 Å/min or less, more preferably 1200 Å/min or more and 6800 Å/min or less, further preferably 1500 Å/min or more and 6500 Å/min or less, and particularly preferably 2000 Å/min or more and 6000 Å/min or less. The polishing speed for a silicon oxide film (preferably a TEOS film) and/or the polishing speed for a silicon nitride film is preferably 15 Å/min or more and 500 Å/min or less, more preferably 20 Å/min or more and 300 Å/min or less, further preferably 25 Å/min or more and 250 Å/min or less, and particularly preferably 50 Å/min or more and 200 Å/min or less. In addition, 1 Å=0.1 nm.

[Selection Ratio]

When the polishing speed (A/min) for a polycrystalline silicon film doped with an n-type impurity (P′poly-Si) is divided by the polishing speed (A/min) for a silicon oxide film (TEOS) and/or a silicon nitride film (SiN) to give a selection ratio, in the present invention, the selection ratio (P′poly-Si/(TEOS or SiN) is preferably 10 or more and 100 or less, more preferably 20 or more and 90 or less, and further preferably 30 or more and 80 or less.

The embodiments of the present invention are described in detail above, but are explanatory and illustrative only, and are not limited. The scope of the present invention should be obviously construed on the basis of the attached claims.

The present invention encompasses the following aspects and embodiments.

1. A polishing composition, containing abrasive grains and a dispersing medium, wherein

the abrasive grains contain first silica particles having a silanol group density of higher than 0 group/nm² and 4 groups/nm² or less and second silica particles having a silanol group density of higher than 4 groups/nm² and 12 groups/nm² or less, and

the pH is higher than 6.

2. The polishing composition according to 1 above, wherein the average secondary particle size of the first silica particles is smaller than the average secondary particle size of the second silica particles.
3. The polishing composition according to 2 above, wherein the average secondary particle size of the first silica particles is 10 nm or more and 200 nm or less, and the average secondary particle size of the second silica particles is 20 nm or more and 300 nm or less.
4. The polishing composition according to any one of 1 to 3 above, wherein the second silica particles have a silanol group density of higher than 5 groups/nm² and 12 groups/nm² or less.
5. The polishing composition according to any one of 1 to 3 above, wherein the second silica particles have a silanol group density of higher than 6 groups/nm² and 12 groups/nm² or less.
6. The polishing composition according to any one of 1 to 5 above, further containing at least one polishing speed-improving agent selected from the group consisting of aminoethylpiperazine and ammonia.
7. The polishing composition according to any one of 1 to 6 above, wherein the pH is 7 or more.
8. The polishing composition according to any one of 1 to 7 above, further containing a pH adjusting agent, wherein the pH adjusting agent contains potassium hydroxide.
9. The polishing composition according to any one of 1 to 8 above, containing substantially no oxidizing agent.
10. The polishing composition according to any one of 1 to 9 above, which is used for an application of polishing an object to be polished containing a polycrystalline silicon film doped with an n-type impurity.
11. The polishing composition according to 10 above, wherein the object to be polished further contains at least one type of film selected from a silicon oxide film and a silicon nitride film.
12. A polishing method, including a step of polishing an object to be polished containing a polycrystalline silicon film doped with an n-type impurity using the polishing composition according to any one of 1 to 11 above.
13. A method for producing a semiconductor substrate, including a step of polishing a semiconductor substrate including a polycrystalline silicon film doped with an n-type impurity by the polishing method according to 12 above.

### EXAMPLES

The present invention will be described in more detail using the following Examples and Comparative Examples, but the technical scope of the present invention is not limited to only the following Examples. Note that unless otherwise specified, “%” and “part(s)” refer to “mass %” and “parts by mass”, respectively. Further, in the following Examples, unless otherwise specified, operation was performed under conditions of room temperature (20° C. to 25° C.)/relative humidity of 40% RH to 50% RH.

[Preparation of Abrasive Grains]

(Preparation of First Silica Particles and Second Silica Particles)

Silica particles having silanol group densities described in Table 1 were prepared as first silica particles and second silica particles. Specifically, first silica particles and second silica particles were, for example, prepared by sintering silica while maintaining the silica under an environment at 120° C. to 200° C. for 30 minutes or longer, so as to adjust the number of silanol groups on the surfaces of silica particles to be desired numerical values such as a value of higher than 0 group/nm² and 4 groups/nm² or less or higher than 4 groups/nm² and 12 groups/nm² or less.
Silica particles a: silanol group density of 1.6 groups/nm², average primary particle size: 30 nm, average secondary particle size: 60 nm, average degree of association: 2
Silica particles b: silanol group density of 3.5 groups/nm², average primary particle size: 30 nm, average secondary particle size: 60 nm, average degree of association: 2
Silica particles c: silanol group density of 7.9 groups/nm², average primary particle size: 90 nm, average secondary particle size: 210 nm, average degree of association: 2.3
Silica particles d: silanol group density of 6.57 groups/nm², average primary particle size: 78 nm, average secondary particle size: 120 nm, average degree of association: 1.6
Silica particles e: silanol group density of 5.7 groups/nm², average primary particle size: 35 nm, average secondary particle size: 70 nm, average degree of association: 2
Silica particles f: silanol group density of 3.8 groups/nm², average primary particle size: 24 nm, average secondary particle size: 50 nm, average degree of association: 2.1

Note that the silanol group densities (unit: group/nm²) of first silica particles and second silica particles were calculated by the following method after measurement and calculation of each parameter by the following measurement method and calculation method.

[Method for Calculating Silanol Group Density]

The silanol group density of the first silica particles and the second silica particles was calculated by the Sears method using neutralization titration described in G. W. Sears, Analytical Chemistry, vol. 28, No. 12, 1956, 1982 to 1983.

More specifically, the silanol group density of the first silica particles and the second silica particles was calculated by the following formula 1, after titration of each type of the first silica particles and the second silica particles as a measurement sample by the above method.

ρ=(c×V×N_{A}×10⁻²¹)/(C×S) Formula 1

In the above Formula 1,

ρ denotes silanol group density (number of groups/nm²);

c denotes the concentration (mol/L) of a sodium hydroxide solution used for titration;

V denotes the volume (L) of the sodium hydroxide solution required to increase pH from 4.0 to 9.0;

N_{A} denotes Avogadro's constant (number of particles/mol); and

S denotes BET specific surface area (nm/g) of silica particles.

[Particle Size of First Silica Particles and Second Silica Particles]

The average primary particle size of abrasive grains (the first silica particles and the second silica particles) was calculated from the specific surface area of abrasive grains as measured by the BET method using “Flow SorbII 2300” (manufactured by Micromeritics) and the density of abrasive grains. Further, the average secondary particle size of abrasive grains (the first silica particles and the second silica particles) was measured with a dynamic light scattering particle size·particle size distribution apparatus UPA-UTI151 (manufactured by NIKKISO CO., LTD.).

[Preparation of Polishing Composition]

### Example 1

The first silica particles: silica particles a (silanol group density of 1.6 group/nm², average primary particle size: 30 nm, average secondary particle size: 60 nm, average degree of association: 2) and second silica particles: silica particles c (silanol group density of 7.9 groups/nm², average primary particle size: 90 nm, average secondary particle size: 210 nm, average degree of association: 2.3) obtained above as abrasive grains were each added to pure water as a dispersing medium at room temperature (25° C.) in such a manner that the final concentrations of silica particles a and silica particles c were 1 mass % and 1.5 mass %, respectively, and aminoethylpiperazine was added as a polishing speed-improving agent to the dispersing medium in such a manner that the final concentration thereof was 0.02 mass %, thereby obtaining a mixed solution.

Subsequently, potassium hydroxide was added as a pH adjusting agent to the mixed solution in such a manner that the pH was 11, and then the solution was stirred and mixed at room temperature (25° C.) for 30 minutes, thereby preparing a polishing composition. The pH of the polishing composition (liquid temperature: 25° C.) was confirmed using a pH meter (manufactured by HORIBA, Ltd. Model No.: LAQUA). Further, the electrical conductivity of the polishing composition was measured using a desktop-type electrical conductivity meter (manufactured by HORIBA, Ltd., Model No.: DS-71).

### Examples 2 to 11 and Comparative Examples 1 to 8

Except for changing the types and the contents of first silica particles and second silica particles, the type and the content of a polishing speed-improving agent, and pH (the type and the content of a pH adjusting agent) as described in Table 1 below, each of the polishing compositions of Examples 2 to 11 and Comparative Examples 1 to 8 was prepared in the same manner as in Example 1. Note that those denoted with “-” in Table 1 below indicate that the relevant agent was not contained. The pH and the electrical conductivity of each polishing composition obtained, and the average secondary particle size of abrasive grains (first silica particles and second silica particles) in each polishing composition are as described in Table 1 below.

In Table 1, “particle size” in the columns of first silica particles and second silica particles indicates the average secondary particle size, “AEP” in the column of polishing speed-improving agent indicates aminoethylpiperazine, “EC” indicates electrical conductivity, and “P′ poly-Si” in the column of polishing speed indicates phosphorus-doped polysilicon, “P′ poly-Si/TEOS” in the column of selection ratio indicates the selection ratio of a phosphorus-doped polysilicon film to a TEOS film. The “P′ poly-Si/TEOS” is calculated by dividing the polishing speed for P′poly-Si by the polishing speed for TEOS.

In Table 1, abrasive grains having a silanol group density of 1.6 group/nm² are silica particles a, abrasive grains having a silanol group density of 3.5 groups/nm² are silica particles b, abrasive grains having a silanol group density of 7.9 groups/nm² are silica particles c, abrasive grains having a silanol group density of 6.57 groups/nm² are silica particles d, abrasive grains having a silanol group density of 5.7 groups/nm² are silica particles e, and abrasive grains having a silanol group density of 3.8 groups/nm² are silica particles f. Further, in Table 1, abrasive grains described in the column of “first silica particles” of Comparative Example 5 correspond to second silica particles in terms of silanol group density, abrasive grains described in the column of “second silica particles” of Comparative example 8 correspond to first silica particles in terms of silanol group density.

The particle sizes (average primary particle size, average secondary particle size) of abrasive grains in the polishing composition were the same as the particle sizes of powdery abrasive grains. In addition, a method for measuring particle size is the same as the above measurement method. Here, in the present invention, a polishing composition containing first silica particles as abrasive grains was prepared (the same constituents were used except for abrasive grains), and then the particle size of the first silica particles in the polishing composition was measured. The same procedure was also performed for second silica particles. This confirmed that particle sizes (average primary particle size, average secondary particle size) of first silica particles and second silica particles in the polishing composition were the same as the particle size of powdery first silica particles and the particle size of powdery second silica particles, respectively.

[Evaluation of Polishing Speed]

The polishing speed when each of the following objects to be polished were polished using each of the above-obtained polishing compositions under the following polishing conditions was measured.

(Polishing apparatus and polishing conditions)

Polishing apparatus: manufactured by Engis Japan Corporation, wrapping machine EJ-380IN-CH

Polishing pad: manufactured by NITTA DuPont Incorporated, hard polyurethane pad IC1010

Polishing pressure: 3.0 psi (1 psi=6894.76 Pa)

Rotation number of platen: 60 rpm

Rotation number of head (carrier): 60 rpm

Supply of polishing composition: flowing (discarded after single use)

Supply amount of polishing composition: 100 mL/minute

Polishing time: 30 seconds

(Object to be Polished)

As an object to be polished, a 300 mm blanket wafer having a 3000 Å thick phosphorus-doped polysilicon (phosphorus content: 20 at %) film formed on the surface was prepared. Further as an object to be polished, a silicon wafer (300 mm, blanket wafer, manufactured by ADVANTEC CO., LTD.) having a TEOS film with a thickness of 10000 Å formed on the surface was prepared. Subsequently, the wafer was cut into 30 mm×30 mm chips to prepare coupons as test specimens, and then a polishing test was conducted. Objects to be polished, which were used for the test, will be described in detail as follows.

Note that the content of impurities (doping level) was an amount with respect to 100 at % of polysilicon and impurities. The content of an n-type impurity, with which polycrystalline silicon is doped, is calculated using the following measurement equipment under the following conditions.

Measurement equipment; Multifunctional scanning X-ray photoelectron spectrometer (XPS)

Equipment name and manufacturer: PHI5000 Versa Probe ULVAC-PHI, INC.

Measurement: In the case of phosphorus-doped polysilicon, elements measured were 4 types, phosphorus, silicon, oxygen, and carbon, the number of sweeps of the measurement equipment was 10 times for each element, and the content of phosphorus (P content)(at %) with respect to 100 at % of polysilicon and phosphorus was calculated by the following formula 2 using the output value of polysilicon (Poly-Si output value; specifically, total output value of Si, 0 and C) and the output value of phosphorus (P output value).

P content (at %)=P output value (%)/(Poly-Si output value (%)+P output value (%)) Formula 2.

(Polishing Speed)

Polishing speed (Removal Rate; RR) was calculated by the following formula.

$$Polishing speed [ Å / min ] = \qquad [ Formula 1 ]$$

$$\frac{\begin{matrix}Film thickness before \\ polishing [ Å ]\end{matrix} - \begin{matrix}Film thickness after \\ polishing [ Å ]\end{matrix}}{Polishing time [ min ]}$$

Film thickness was determined using a light interference type film thickness measurement apparatus (manufactured by Dainippon Screen Mfg. Co., Ltd., Model: Lambda Ace VM-2030), and then the difference between the film thickness before polishing and the same after polishing was divided by polishing time for evaluation of the polishing speed.

The results of evaluating the polishing speed for the phosphorus-doped polysilicon film and the polishing speed for the TEOS film are shown in Table 1 below.

TABLE 1

| | First silica particles | | | Second silica particles | | | | |
|---|---|---|---|---|---|---|---|---|
| | | | Silanol | | | Silanol | Polishing | |
| | | | group | | | group | speed-improving | |
| | | Particle | density | | Particle | density | agent | |
| | Concentration | size | number of | Concentration | size | number of | | Concentration |
| | mass % | nm | groups/nm² | mass % | nm | groups/nm² | Compound | mass % |
| Example 1 | 1 | 60 | 1.6 | 1.5 | 210 | 7.9 | AEP | 0.02 |
| Example 2 | 0.75 | 60 | 1.6 | 0.75 | 120 | 6.57 | AEP | 0.1 |
| Example 3 | 0.75 | 60 | 1.6 | 0.75 | 210 | 7.9 | AEP | 0.1 |
| Example 4 | 0.75 | 60 | 1.6 | 0.75 | 210 | 7.9 | AEP | 0.1 |
| Example 5 | 0.75 | 60 | 1.6 | 0.75 | 120 | 6.57 | AEP | 0.1 |
| Example 6 | 0.75 | 60 | 1.6 | 0.75 | 120 | 6.57 | NH₃ | 0.1 |
| Example 7 | 0.75 | 60 | 3.5 | 0.75 | 70 | 5.7 | — | — |
| Example 8 | 0.75 | 60 | 1.6 | 0.75 | 120 | 6.57 | — | — |
| Example 9 | 0.75 | 60 | 1.6 | 0.75 | 70 | 5.7 | — | — |
| Example 10 | 0.75 | 60 | 1.6 | 0.75 | 210 | 7.9 | — | — |
| Example 11 | 0.75 | 60 | 3.5 | 0.75 | 210 | 7.9 | — | — |
| Comparative | 1.5 | 60 | 1.6 | — | — | — | — | — |
| Example 1 | | | | | | | | |
| Comparative | — | — | — | 1.5 | 120 | 6.57 | — | — |
| Example 2 | | | | | | | | |
| Comparative | — | — | — | 1.5 | 70 | 5.7 | — | — |
| Example 3 | | | | | | | | |
| Comparative | 1.5 | 60 | 3.5 | — | — | — | — | — |
| Example 4 | | | | | | | | |
| Comparative | 0.75 | 120 | 6.57 | 0.75 | 70 | 5.7 | — | — |
| Example 5 | | | | | | | | |
| Comparative | 0.75 | 60 | 1.6 | 0.75 | 210 | 7.9 | — | — |
| Example 6 | | | | | | | | |
| Comparative | 0.75 | 60 | 3.5 | 0.75 | 210 | 7.9 | — | — |
| Example 7 | | | | | | | | |
| Comparative | 1.5 | 60 | 1.6 | 0.75 | 50 | 3.8 | — | — |
| Example 8 | | | | | | | | |

| | pH | Physical | | | | Selection |
|---|---|---|---|---|---|---|
| | adjusting | property | | Polishing speed | | ratio |
| | agent | pH | EC | P′poly-Si | TEOS | P′poly- |
| | Component | [—] | [mS/cm] | [Å/min] | [Å/min] | Si/TEOS |
| Example 1 | KOH | 11 | 4 | 3320 | 154 | 22 |
| Example 2 | NH₃ | 11 | 1 | 2980 | 43 | 69 |
| Example 3 | NH₃ | 11 | 1 | 3098 | 46 | 67 |
| Example 4 | NH₃, KOH | 11 | 2 | 2998 | 65 | 46 |
| Example 5 | KOH | 11 | 3 | 2300 | 74 | 31 |
| Example 6 | NH₃ | 11 | 1 | 2200 | 34 | 65 |
| Example 7 | KOH | 11 | 3 | 1180 | 52 | 23 |
| Example 8 | KOH | 11 | 3 | 1560 | 78 | 20 |
| Example 9 | KOH | 11 | 3 | 1280 | 62 | 21 |
| Example 10 | KOH | 11 | 3 | 1780 | 83 | 21 |
| Example 11 | KOH | 11 | 3 | 1739 | 92 | 19 |
| Comparative | KOH | 11 | 3 | 806 | 73 | 11 |
| Example 1 | | | | | | |
| Comparative | KOH | 11 | 3 | 798 | 43 | 19 |
| Example 2 | | | | | | |
| Comparative | KOH | 11 | 3 | 720 | 38 | 19 |
| Example 3 | | | | | | |
| Comparative | KOH | 11 | 3 | 801 | 68 | 12 |
| Example 4 | | | | | | |
| Comparative | KOH | 11 | 3 | 790 | 42 | 19 |
| Example 5 | | | | | | |
| Comparative | HNO₃ | 4 | 1 | 230 | 1020 | 0 |
| Example 6 | | | | | | |
| Comparative | HNO₃ | 4 | 1 | 130 | 430 | 0 |
| Example 7 | | | | | | |
| Comparative | KOH | 11 | 3 | 745 | 46 | 16 |
| Example 8 | | | | | | |

As shown in Table 1, the use of the polishing compositions of Examples 1 to 11 resulted in the polishing speeds each exceeding 1000 Å/min for the phosphorus-doped polysilicon film, revealing that the polishing compositions of Examples 1 to 11 are capable of polishing the phosphorus-doped polysilicon film at higher polishing speeds compared with the polishing compositions of Comparative Examples 1 to 8.

Further, as shown in Table 1, the use of the polishing compositions of Examples 1 to 11 resulted in the polishing speeds each exceeding 40 Å/min for the TEOS film, and the selection ratio of the phosphorus-doped polysilicon film to the TEOS film of 19 or more, revealing that the polishing compositions of Examples 1 to 11 are capable of polishing the phosphorus-doped polysilicon film and the TEOS film at higher polishing speeds compared with the polishing compositions of Comparative Examples 1 to 8 while exhibiting a higher selection ratio of the phosphorus-doped polysilicon film to the TEOS film compared with the same.

As described above, it was found that the polishing composition can improve the polishing speed of an object to be polished by containing two types of silica particles with different silanol group densities as abrasive grains.

The present application is based on the Japanese patent application No. 2021-049532 filed on Mar. 24, 2021, and the disclosed content thereof is incorporated herein by reference in their entirety.

1. A polishing composition, comprising abrasive grains and a dispersing medium, wherein
the abrasive grains contain first silica particles having a silanol group density of higher than 0 group/nm² and 4 groups/nm² or less and second silica particles having a silanol group density of higher than 4 groups/nm² and 12 groups/nm² or less, and
the pH is higher than 6.

2. The polishing composition according to claim 1, wherein the average secondary particle size of the first silica particles is smaller than the average secondary particle size of the second silica particles.

3. The polishing composition according to claim 2, wherein the average secondary particle size of the first silica particles is 10 nm or more and 200 nm or less, and the average secondary particle size of the second silica particles is 20 nm or more and 300 nm or less.

4. The polishing composition according to claim 1, wherein the second silica particles have a silanol group density of higher than 5 groups/nm² and 12 groups/nm² or less.

5. The polishing composition according to claim 1, wherein the second silica particles have a silanol group density of higher than 6 groups/nm² and 12 groups/nm² or less.

6. The polishing composition according to claim 1, further containing at least one polishing speed-improving agent selected from the group consisting of aminoethylpiperazine and ammonia.

7. The polishing composition according to claim 1, wherein the pH is 7 or more.

8. The polishing composition according to claim 1, further comprising a pH adjusting agent, wherein the pH adjusting agent contains potassium hydroxide.

9. The polishing composition according to claim 1, comprising substantially no oxidizing agent.

10. The polishing composition according to claim 1, which is used for an application of polishing an object to be polished containing a polycrystalline silicon film doped with an n-type impurity.

11. The polishing composition according to claim 10, wherein the object to be polished further contains at least one type of film selected from a silicon oxide film and a silicon nitride film.

12. A polishing method, comprising a step of polishing an object to be polished containing a polycrystalline silicon film doped with an n-type impurity using the polishing composition according to claim 1.

13. A method for producing a semiconductor substrate, comprising a step of polishing a semiconductor substrate including a polycrystalline silicon film doped with an n-type impurity by the polishing method according to claim 12.
